(19) United States
(12) Patent Application Publication
(10) Pub. No.: US 2018/0294255 A1
(43) Pub. Date: Oct. 11, 2018

(54) METHOD FOR FABRICATING MICROELECTRONIC PACKAGE WITH SURFACE MOUNTED PASSIVE ELEMENT

(71) Applicant: MEDIATEK INC., Hsin-Chu (TW)

(72) Inventor: Hsing-Chih Liu, Taichung City (TW)

(21) Appl. No.: 15/886,813

(22) Filed: Feb. 1, 2018

Related U.S. Application Data
(60) Provisional application No. 62/483,970, filed on Apr. 11, 2017.

(51) Int. Cl. H01L 25/00; H01L 23/522; H01L 25/16; H01L 23/00; H01L 21/56

(52) U.S. Cl. CPC H01L 25/50; H01L 23/5226; H01L 25/16; H01L 24/03; H01L 24/11; H01L 24/17; H01L 2924/30101; H01L 24/81; H01L 21/563; H01L 2224/02379; H01L 2224/0231; H01L 2224/0401; H01L 24/14

(57) ABSTRACT

A method for fabricating a microelectronic package is disclosed. A packaged substrate having a chip surrounded by a molding compound is prepared. An RDL structure is formed on the chip. Bump pads and SMD pads are disposed in a topmost level of metal interconnect of the RDL structure. A passivation layer covers the RDL structure. The passivation layer is subjected to a lithographic process to form bump pad openings and an SMD opening in the passivation layer. The bump pads are exposed, respectively, through the bump pad openings. The SMD pads are exposed through the SMD opening. Bumps are formed on the bump pads through the bump pad openings, respectively. A passive element is mounted on the SMD pads.

### CROSS REFERENCE TO RELATED APPLICATIONS

This application claims priorities from U.S. provisional application No. 62/483,970 filed Apr. 11, 2017, which is included herein in its entirety by reference.

### BACKGROUND

As system complexity and operational speeds increase, the power consumption of integrated circuits increases dramatically. Additionally, the IC supply voltage continues to drop with the inevitable scaling of VLSI technology.

Reducing the nominal supply voltage is accompanied by a reduction in device noise margins, making components more vulnerable to power supply noise. This noise consists of the dynamic AC voltage fluctuation due to the frequency dependent distributed parasitics inherent in today's power distribution systems, and the DC voltage drop (i.e., “IR” drop).

In a microelectronic system, the system's IR drop may be budgeted into three portions: on-chip, package and board. On-chip IR drop has been extensively studied because the resistive loss is severe due to the fine feature-size of the on-die power grid.

To reduce the IR drop and improve power integrity, decoupling capacitors are typically mounted on a top surface of a packaging substrate or disposed within the packaging substrate. However, the aforesaid substrate-level decoupling capacitors are still not close enough to the IC die in the package to cope with the on-chip IR drop.

There is a need in this technical field to provide a method for fabricating an improved microelectronic package with surface mounted passive element such as a decoupling capacitor disposed in close proximity to the IC die.

### SUMMARY

It is an objective of the claimed invention to provide a method for fabricating an improved microelectronic package with surface mounted passive element such as a decoupling capacitor disposed in close proximity to the IC die, which is capable of reducing the IR drop and improving power integrity, and is cost-effective.

According to one aspect of the invention, a method for fabricating a microelectronic package is disclosed. A packaged substrate having thereon at least one chip surrounded by a molding compound is prepared. A re-distribution layer (RDL) structure is formed on the chip. The RDL structure comprises n levels of metal interconnect, wherein n is an integer that is greater than or equal to 2. Bump pads and surface mount device (SMD) pads are disposed in a topmost level of the n levels of metal interconnect of the RDL structure. A passivation layer covers the RDL structure. The passivation layer is subjected to a lithographic process to form bump pad openings and an SMD opening in the passivation layer. The bump pads are exposed, respectively, through the bump pad openings. The SMD pads are exposed through the SMD opening. Bumps are formed on the bump pads through the bump pad openings, respectively. A passive element is mounted on the SMD pads.

According to another aspect of the invention, a method for fabricating a microelectronic package is disclosed. A packaged substrate having thereon at least one chip surrounded by a molding compound is prepared. A re-distribution layer (RDL) structure is formed on the chip. The RDL structure comprises n levels of metal interconnect, wherein n is an integer that is greater than or equal to 2. Bump pads and surface mount device (SMD) pads are disposed in a topmost level of the n levels of metal interconnect of the RDL structure. A passivation layer covers the RDL structure. The passivation layer is subjected to a lithographic process to form bump pad openings in the passivation layer. The bump pads are exposed, respectively, through the bump pad openings. Under-bump metallization (UBM) pads and SMD pads are formed on the passivation layer. Solder balls or bumps are formed on the UBM pads, respectively. A passive element is mounted on the SMD pads.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 to FIG. 5 are schematic, cross-sectional diagrams showing a method for fabricating a microelectronic package with surface mounted passive element in accordance with one embodiment of the invention;

FIG. 6 to FIG. 9 are schematic, cross-sectional diagrams showing a method for fabricating a microelectronic package with surface mounted passive element in accordance with another embodiment of the invention; and

FIG. 10 to FIG. 13 are schematic, cross-sectional diagrams showing a method for fabricating a microelectronic package with surface mounted passive element in accordance with still another embodiment of the invention

### DETAILED DESCRIPTION

In the following detailed description of embodiments of the invention, reference is made to the accompanying drawings, which form a part hereof, and in which is shown by way of illustration specific preferred embodiments in which the disclosure may be practiced.

These embodiments are described in sufficient detail to enable those skilled in the art to practice them, and it is to be understood that other embodiments may be utilized and that mechanical, chemical, electrical, and procedural changes may be made without departing from the spirit and scope of the present disclosure. The following detailed description is, therefore, not to be taken in a limiting sense, and the scope of embodiments of the present invention is defined only by the appended claims.

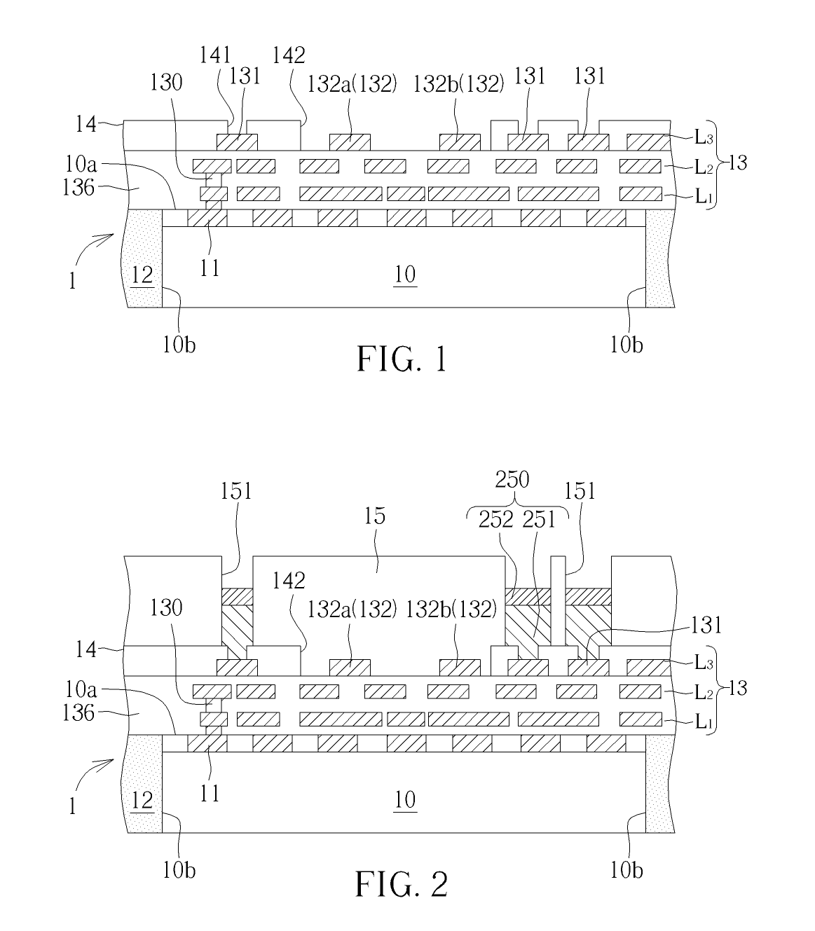

FIG. 1 to FIG. 5 are schematic, cross-sectional diagrams showing a method for fabricating a microelectronic package with surface mounted passive element such as a decoupling capacitor disposed in close proximity to the IC die in accordance with one embodiment of the invention.

As shown in FIG. 1, a packaged substrate 1 is provided. For example, the packaged substrate 1 may comprise a fan-out wafer-level-package (Fan-Out WLP). The packaged substrate 1 comprises one chip (or die) 10. The chip 10 has an active surface 10a and four side edges 10b. The four side edges 10b of the chip 10 are encapsulated and surrounded by a molding compound 12. A plurality of input/output (I/O) pads 11 are provided on the active surface 10a.

A re-distribution layer (RDL) structure 13 is formed directly on the active surface 10a to fan out the I/O pads 11, thereby forming a plurality of bump pads 131 having a looser pad pitch. Depending upon the design requirements, the RDL structure 13 may comprise n levels of metal (e.g., copper) interconnect. According to the illustrative embodiment, n is an integer that is greater than or equal to 2. The bump pads 131 are situated in the topmost level of metal interconnect.

According to the illustrative embodiment, for example, the RDL structure 13 may comprise two lower levels of metal interconnect L₁, L₂ in the dielectric layer 136, and a topmost level of metal interconnect L₃ on the dielectric layer 136. The plurality of bump pads 131 is disposed in the topmost level of metal interconnect L₃.

According to the illustrative embodiment, the lower levels of metal interconnect may be interconnected to the upper level of metal interconnect through the metal via 130. Further, according to the illustrative embodiment, surface mount device (SMD) pads 132 including a ground I/O pad 132a and a power I/O pad 132b are disposed in the topmost level of metal interconnect L₃.

According to the illustrative embodiment, for example, the topmost level of metal interconnect L₃ may be covered with a passivation layer 14 such as a polyimide layer. The passivation layer 14 may be composed of a photo-sensitive material. The passivation layer 14 is then subjected to a lithographic process to form openings (bump pad openings) 141 and an opening (SMD opening) 142. It is to be understood that multiple SMD openings 142 may be formed in the passivation layer 14 according to another embodiment.

Through the openings 141, the underlying bump pads 131 are exposed, respectively. Through the opening 142, the underlying ground I/O pad 132a and power I/O pad 132b are exposed. In an exemplary embodiment, the aforesaid polyimide layer may be composed of low-temperature polybenzoxazole (PBO), but is not limited thereto.

As shown in FIG. 2, a mask layer 15 is formed on the passivation layer 14. For example, the mask layer 15 may be composed of a photo-sensitive material. The mask layer 15 is then subjected to a lithographic process to form openings 151 corresponding to the openings 141, while the opening 142 is completely covered with the mask layer 15.

A plating process is then performed to form a bump 250 (e.g., a C4 bump) including, but not limited to, a metal stud 251 such as a copper stud, and a solder layer 252 on the metal stud 251, in each opening 151. Although not explicitly shown in the figures, it is understood that each bump 250 may further comprise under-bump metallization (UBM) layer.

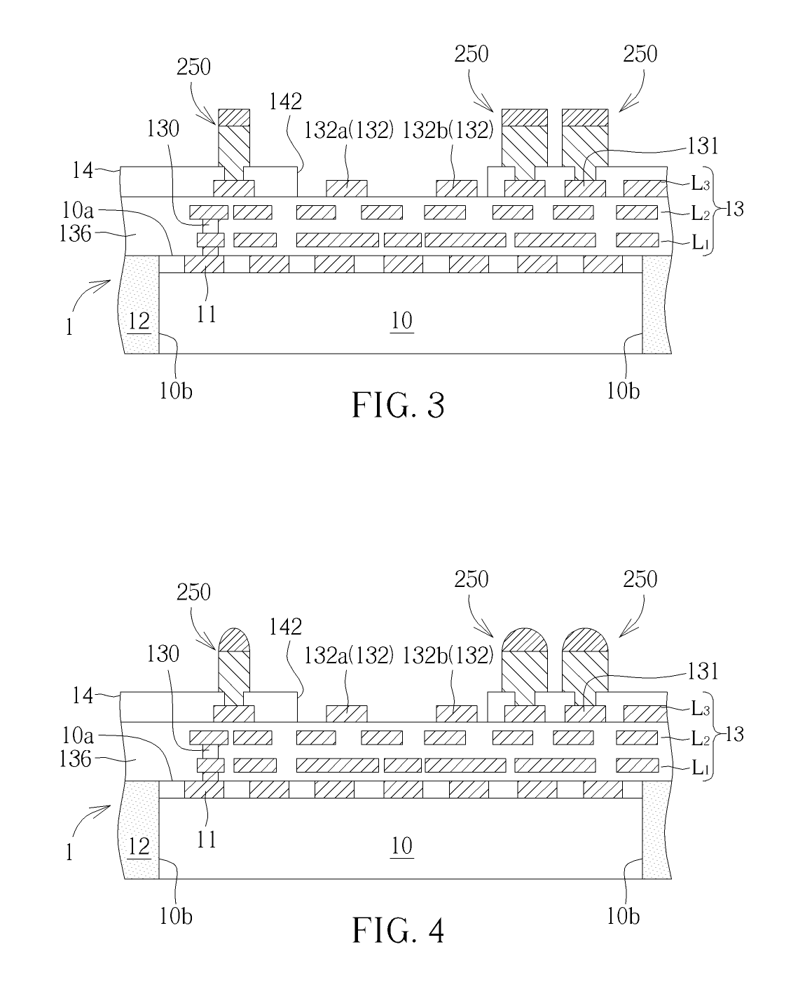

As shown in FIG. 3, after the formation of the bumps 250, the mask layer 15 is removed. The passivation layer 14, the opening 142, and the ground I/O pad 132a and power I/O pad 132b are revealed.

As shown in FIG. 4, a solder reflow (C4 bump reflow) process is performed. The reflow process may be performed in a programmable oven or furnace having, for example, resistive heaters or infrared (IR) lamps, and, depending on the composition of the solder material, maybe performed at reflow temperatures in the range of approximately 200-300° C.

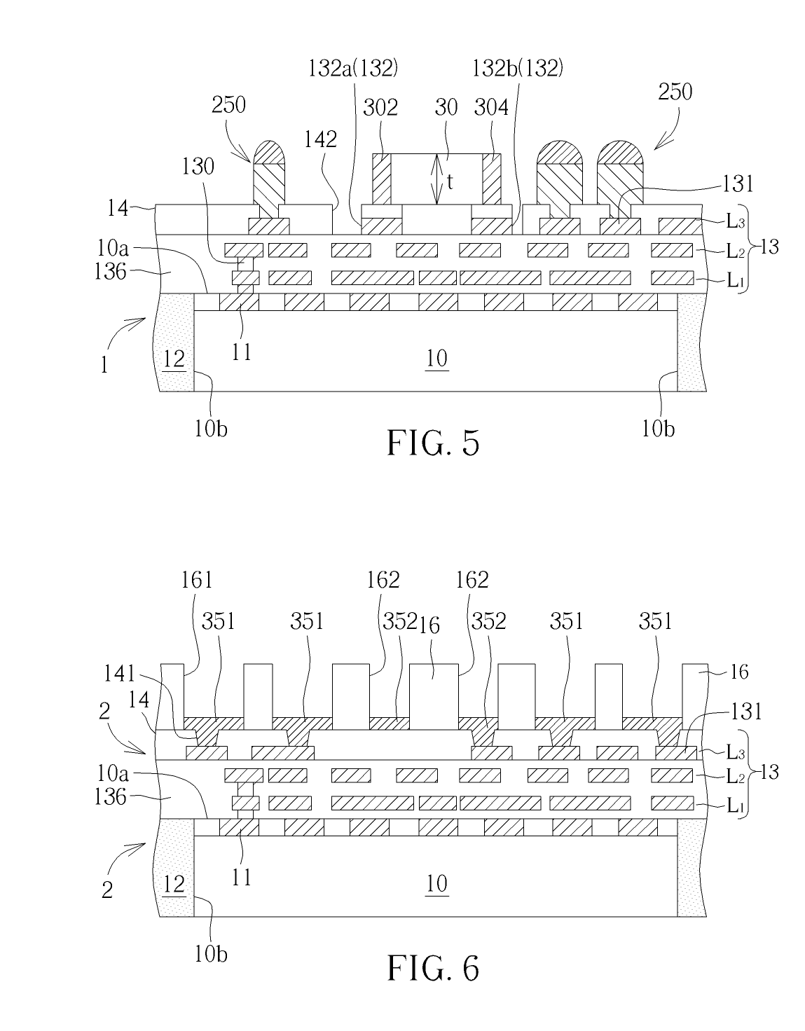

As shown in FIG. 5, after the reflow process is performed, a pre-cleaning process is carried out to remove unwanted substance from the exposed top surfaces of the ground I/O pad 132a and power I/O pad 132b. Subsequently, a discrete passive element 30 such as a decoupling capacitor, a resistor, an inductor, or any suitable integrated passive device (IPD) is mounted directly on the ground I/O pad 132a and power I/O pad 132b. The discrete passive element 30 may be mounted onto the ground I/O pad 132a and power I/O pad 132b by using a pick and place technique, but is not limited thereto. Subsequently, a solder reflow (SMD reflow) process may be performed to firmly attach the discrete passive element 30 to the SMD pads 132.

According to the illustrative embodiment, the discrete passive element 30 may be a decoupling capacitor and may include a terminal 302 and a terminal 304. According to the illustrative embodiment, the terminals 302 and 304 maybe electrically connected to the ground I/O pad 132a and power I/O pad 132b, respectively.

According to the illustrative embodiment, the discrete passive element 30 may have a thickness t ranging between 20-30 micrometers. Since the SMD pads 132 are disposed in the topmost level of the metal interconnect L₃ of the RDL structure 13, the top surface of the discrete passive element 30 is lower than the top surface of each of the bumps 250.

FIG. 6 to FIG. 9 are schematic, cross-sectional diagrams showing a method for fabricating a microelectronic package with surface mounted passive element in accordance with another embodiment of the invention, wherein like numeral numbers designate like layers, regions or elements.

As shown in FIG. 6, a packaged substrate 2 is provided. The packaged substrate 2 may comprise a fan-out wafer-level-package (Fan-Out WLP). The packaged substrate 2 comprises at least one chip (or die) 10. The chip 10 has an active surface 10a and four side edges 10b. The four side edges 10b of the chip 10 are encapsulated and surrounded by a molding compound 12. A plurality of I/O pads 11 are provided on the active surface 10a.

Likewise, an RDL structure 13 is formed directly on the active surface 10a to fan out the I/O pads 11, thereby forming a plurality of bump pads 131 having a looser pad pitch. Depending upon the design requirements, the RDL structure 13 may comprise n levels of metal (e.g., copper) interconnect, wherein n is greater than or equal to 2, and the bump pads 131 are situated in the topmost level of metal interconnect.

According to the illustrative embodiment, for example, the RDL structure 13 may comprise two lower levels of metal interconnect L₁, L₂ in the dielectric layer 136, and a topmost level of metal interconnect L₃ on the dielectric layer 136. The plurality of bump pads 131 is disposed in the topmost level of metal interconnect L₃.

According to the illustrative embodiment, for example, the topmost level of metal interconnect L₃ may be covered with a passivation layer 14 such as a polyimide layer. The passivation layer 14 may be composed of a photo-sensitive material. The passivation layer 14 is then subjected to a lithographic process to form openings (bump pad openings) 141. Through the openings 141, the underlying bump pads 131 are exposed, respectively.

A mask layer 16 is then formed on the passivation layer 14. For example, the mask layer 16 may be composed of a photo-sensitive material such as a photoresist layer. The mask layer 16 is then subjected to a lithographic process to form openings 161 corresponding to the openings 141 and openings 162 for SMD pad formation.

A plating process is then performed to form an under-bump metallization (UBM) pad 351 in each of the openings 161 and a SMD pad 352 in each opening 162. The UBM pads 351 and the SMD pads 352 maybe formed in a substantially conformal manner above the patterned passivation layer 14 so as to cover the exposed upper surface of the bump pad 131, the sidewall surfaces of the opening 141, and the upper surfaces of the passivation layer 14.

According to the illustrative embodiment, the UBM pad 351 and the SMD pad 352 may include a plurality of individual layers, each of which may be individually adapted to provide the requisite adhesion, barrier, protection, and conductivity characteristics. According to the illustrative embodiment, the UBM pad 351 and the SMD pad 352 have identical film structure and film composition.

For example, the UBM pad 351 and the SMD pad 352 may include, but not necessarily be limited to, a titanium-tungsten/chromium-copper/copper (TiW/CrCu/Cu) layer stack, a chromium/chromium-copper/copper (Cr/CrCu/Cu) layer stack, a titanium-tungsten/copper (TiW/Cu) layer stack, a titanium/copper/nickel (Ti/Cu/Ni) layer stack, a titanium-tungsten/nickel-vanadium/copper (TiW/NiV/Cu) layer stack, and the like.

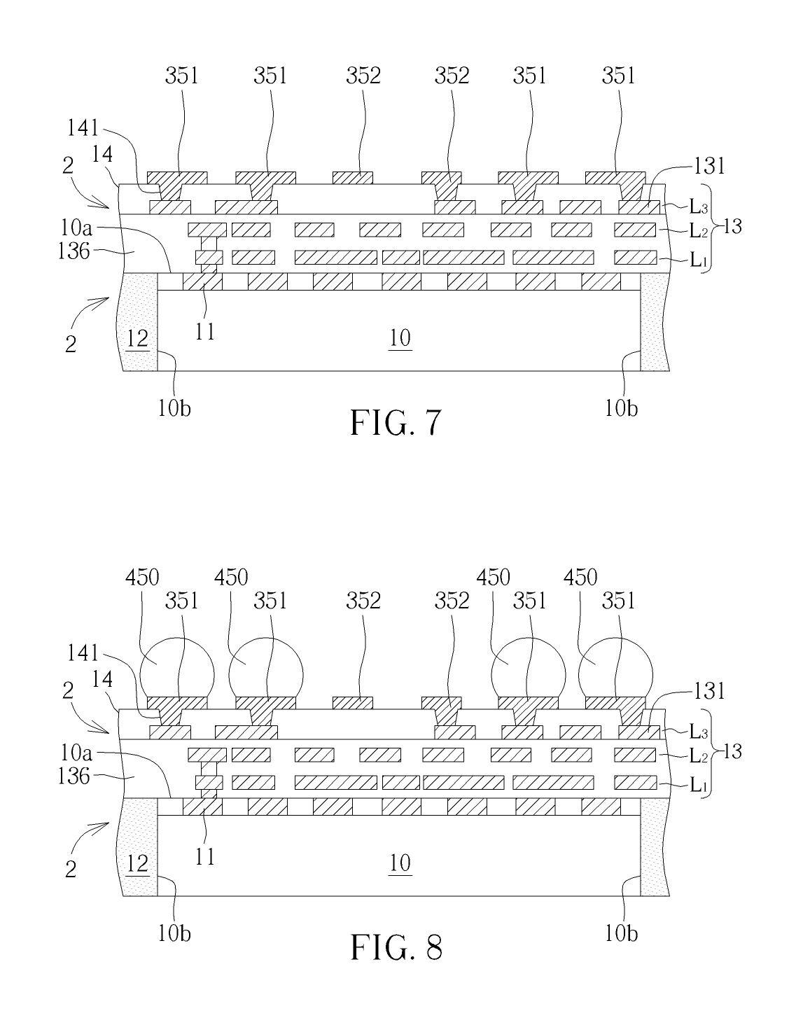

As shown in FIG. 7, after the formation of the UBM pad 351 and the SMD pad 352, the mask layer 16 is removed.

As shown in FIG. 8, subsequently, solder balls or bumps (e.g., C4 bumps) 450 are formed on the UBM pads 351, respectively.

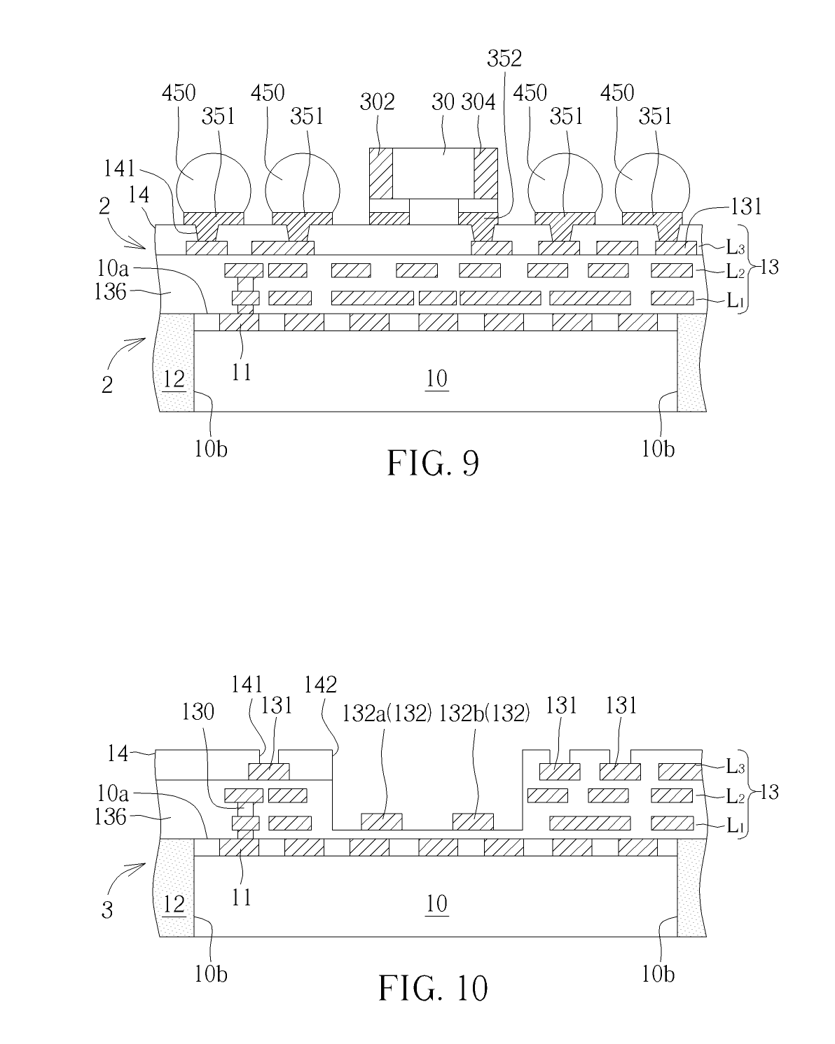

As shown in FIG. 9, a pre-cleaning process may be carried out to remove unwanted substance from the exposed top surfaces of the SMD pad 352. Subsequently, a discrete passive element 30 such as a decoupling capacitor, a resistor, an inductor, or any suitable integrated passive device (IPD) is mounted directly on the SMD pad 352.

According to the illustrative embodiment, the discrete passive element 30 may be a decoupling capacitor and may include a terminal 302 and a terminal 304. According to the illustrative embodiment, the terminals 302 and 304 may be electrically connected to the SMD pad 352 using solder, respectively. A solder reflow process may be performed to firmly attach the discrete passive element 30 to the SMD pad 352.

FIG. 10 to FIG. 13 are schematic, cross-sectional diagrams showing a method for fabricating a microelectronic package with surface mounted passive element in accordance with still another embodiment of the invention, wherein like numeral numbers designate like layers, regions or elements.

As shown in FIG. 10, a packaged substrate 3 is provided. For example, the packaged substrate 3 may comprise a fan-out wafer-level-package (Fan-Out WLP). The packaged substrate 3 comprises one chip (or die) 10. The chip 10 has an active surface 10a and four side edges 10b. The four side edges 10b of the chip 10 are encapsulated and surrounded by a molding compound 12. A plurality of input/output (I/O) pads 11 are provided on the active surface 10a.

A re-distribution layer (RDL) structure 13 is formed directly on the active surface 10a to fan out the I/O pads 11, thereby forming a plurality of bump pads 131 having a looser pad pitch. Depending upon the design requirements, the RDL structure 13 may comprise n levels of metal (e.g., copper) interconnect. According to the illustrative embodiment, n is an integer that is greater than or equal to 2. The bump pads 131 are situated in the topmost level of metal interconnect.

According to the illustrative embodiment, for example, the RDL structure 13 may comprise two lower levels of metal interconnect L₁, L₂ in the dielectric layer 136, and a topmost level of metal interconnect L₃ on the dielectric layer 136. The plurality of bump pads 131 is disposed in the topmost level of metal interconnect L₃.

According to the illustrative embodiment, the lower levels of metal interconnect may be interconnected to the upper level of metal interconnect through the metal via 130. Further, according to the illustrative embodiment, surface mount device (SMD) pads 132 including a ground I/O pad 132a and a power I/O pad 132b are disposed in the lowest level of metal interconnect L₁.

According to the illustrative embodiment, for example, the topmost level of metal interconnect L₃ may be covered with a passivation layer 14 such as a polyimide layer. The passivation layer 14 may be composed of a photo-sensitive material. The passivation layer 14 is subjected to a lithographic process to form openings (bump pad openings) 141 and an opening (SMD opening) 142. It is to be understood that multiple SMD openings 142 may be formed in the passivation layer 14 according to another embodiment.

It is to be understood that the formation of the SMD opening 142 and the formation of the bump pad openings 141 may be completed in different lithographic processes, and an additional etching process maybe required to form the SMD opening 142. These lithographic processes and etching processes are known in the art and the details thereof are omitted.

Through the openings 141, the bump pads 131 are exposed, respectively. Through the opening 142, the ground I/O pad 132a and power I/O pad 132b are exposed. In an exemplary embodiment, the aforesaid polyimide layer may be composed of low-temperature polybenzoxazole (PBO), but is not limited thereto.

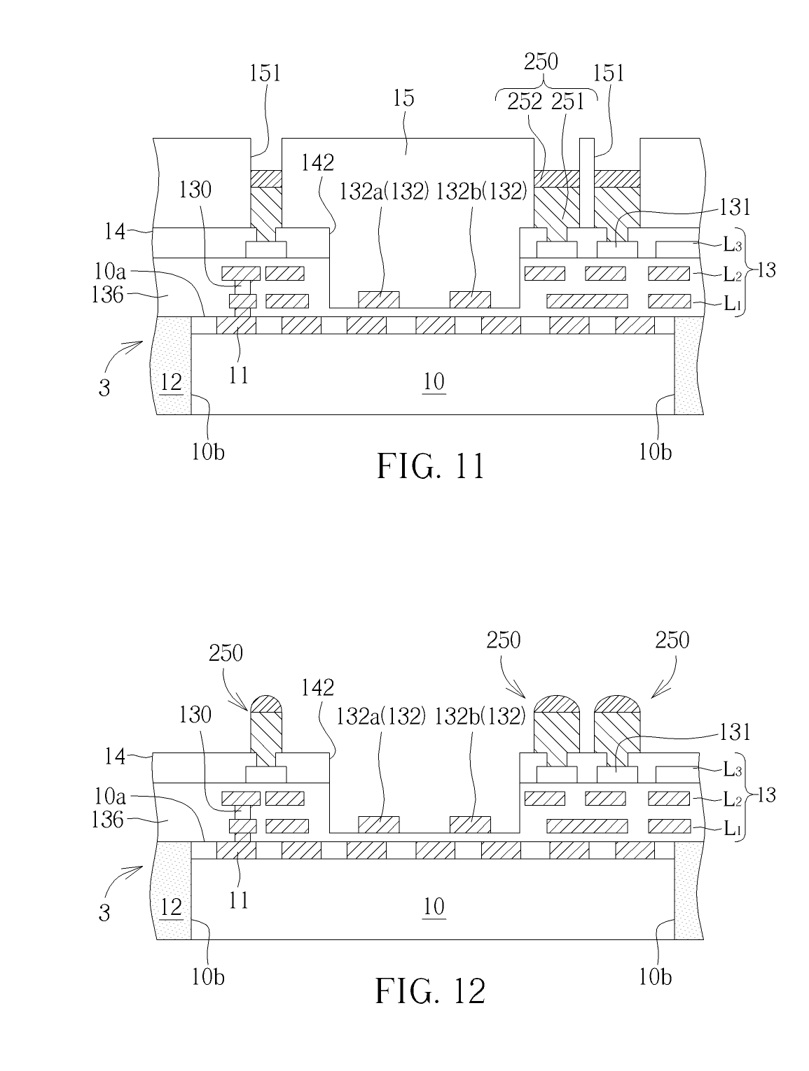

As shown in FIG. 11, a mask layer 15 is formed on the passivation layer 14. For example, the mask layer 15 may be composed of a photo-sensitive material. The mask layer 15 is then subjected to a lithographic process to form openings 151 corresponding to the openings 141, while the opening 142 is completely covered with the mask layer 15.

A plating process is then performed to form a bump 250 (e.g., a C4 bump) including, but not limited to, a metal stud 251 such as a copper stud, and a solder layer 252 on the metal stud 251, in each opening 151. Although not explicitly shown in the figures, it is understood that each bump 250 may further comprise under-bump metallization (UBM) layer.

As shown in FIG. 12, after the formation of the bumps 250, the mask layer 15 is removed. The passivation layer 14, the opening 142, and the ground I/O pad 132a and power I/O pad 132b are revealed. A solder reflow (C4 bump reflow) process is then performed. The reflow process may be performed in a programmable oven or furnace having, for example, resistive heaters or infrared (IR) lamps, and, depending on the composition of the solder material, may be performed at reflow temperatures in the range of approximately 200-300° C. After the reflow process is performed, a pre-cleaning process may be carried out to remove unwanted substance from the exposed top surfaces of the ground I/O pad 132a and power I/O pad 132b.

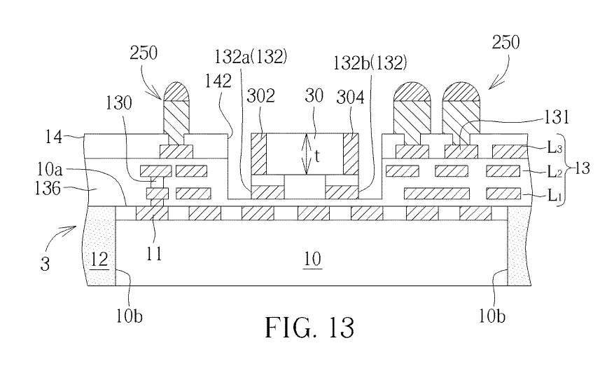

Subsequently, as shown in FIG. 13, a discrete passive element 30 such as a decoupling capacitor, a resistor, an inductor, or any suitable integrated passive device (IPD) is mounted directly on the ground I/O pad 132a and power I/O pad 132b. The discrete passive element 30 may be mounted onto the ground I/O pad 132a and power I/O pad 132b by using a pick and place technique, but is not limited thereto. Subsequently, a solder reflow (SMD reflow) process may be performed to firmly attach the discrete passive element 30 to the SMD pads 132.

According to the illustrative embodiment, the discrete passive element 30 may be a decoupling capacitor and may include a terminal 302 and a terminal 304. According to the illustrative embodiment, the terminals 302 and 304 may be electrically connected to the ground I/O pad 132a and power I/O pad 132b, respectively.

The SMD pads 132 are disposed in the lowest level of the metal interconnect L₁ of the RDL structure 13 within the SMD opening 142 that partially recessed into the dielectric layer 136 to ensure that the top surface of the discrete passive element 30 is lower than the top surface of each of the bumps 250.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a microelectronic package, comprising:
providing a packaged substrate having thereon at least one chip surrounded by a molding compound;
forming a re-distribution layer (RDL) structure on the chip, the RDL structure comprising n levels of metal interconnect, wherein n is an integer that is greater than or equal to 2, wherein bump pads and surface mount device (SMD) pads are disposed in a topmost level of the n levels of metal interconnect of the RDL structure;
forming a passivation layer covering the RDL structure;
subjecting the passivation layer to a lithographic process to form bump pad openings and an SMD opening in the passivation layer, wherein the bump pads are exposed, respectively, through the bump pad openings, and the SMD pads are exposed through the SMD opening;
forming bumps on the bump pads through the bump pad openings, respectively; and
mounting a passive element on the SMD pads.

2. The method for fabricating a microelectronic package according to claim 1, wherein the passivation layer comprises a polyimide layer.

3. The method for fabricating a microelectronic package according to claim 1, wherein the bumps comprises C4 bumps.

4. The method for fabricating a microelectronic package according to claim 1, wherein each of the bumps comprises a metal stud and a solder layer on the metal stud.

5. The method for fabricating a microelectronic package according to claim 1, wherein before mounting the passive element on the SMD pads, the method further comprises:
performing a pre-cleaning process to remove unwanted substance from an exposed top surfaces of the SMD pads.

6. The method for fabricating a microelectronic package according to claim 1, wherein the passive element comprises a decoupling capacitor, a resistor, an inductor, or an integrated passive device (IPD).

7. The method for fabricating a microelectronic package according to claim 1, wherein the passive element has a thickness t ranging between 20-30 micrometers.

8. The method for fabricating a microelectronic package according to claim 1, wherein a top surface of the passive element is lower than a top surface of each of the bumps.

9. The method for fabricating a microelectronic package according to claim 1, wherein the packaged substrate comprises a fan-out wafer-level-package (Fan-Out WLP).

10. A method for fabricating a microelectronic package, comprising:
providing a packaged substrate having thereon at least one chip surrounded by a molding compound;
forming a re-distribution layer (RDL) structure on the chip, the RDL structure comprising n levels of metal interconnect, wherein n is an integer that is greater than or equal to 2, wherein bump pad and surface mount device (SMD) pads are disposed in a topmost level of the n levels of metal interconnect of the RDL structure;
forming a passivation layer covering the RDL structure;
subjecting the passivation layer to a lithographic process to form bump pad openings in the passivation layer, wherein the bump pads are exposed, respectively, through the bump pad openings;
forming under-bump metallization (UBM) pads and SMD pads on the passivation layer;
forming solder balls or bumps on the UBM pads, respectively; and
mounting a passive element on the SMD pads.

11. The method for fabricating a microelectronic package according to claim 10, wherein said forming UBM pads and SMD pads on the passivation layer comprises:
forming a mask layer on the passivation layer;
subjecting the mask layer to a lithographic process to form openings in the mask layer; and
performing a plating process to form the UBM pads and SMD pads in the openings, respectively.

12. The method for fabricating a microelectronic package according to claim 11, wherein after forming the UBM pads and the SMD pads on the passivation layer, the mask layer is removed.

13. The method for fabricating a microelectronic package according to claim 11, wherein the mask layer is a photoresist layer.

14. The method for fabricating a microelectronic package according to claim 10, wherein the passive element comprises a decoupling capacitor, a resistor, an inductor, or an integrated passive device (IPD).

15. The method for fabricating a microelectronic package according to claim 10, wherein the packaged substrate comprises a fan-out wafer-level-package (Fan-Out WLP).

16. A method for fabricating a microelectronic package, comprising:
providing a packaged substrate having thereon at least one chip surrounded by a molding compound;
forming a re-distribution layer (RDL) structure on the chip, the RDL structure comprising n levels of metal interconnect in a dielectric layer, wherein n is an integer that is greater than or equal to 2, wherein bump pads are disposed in a topmost level of the n levels of metal interconnect of the RDL structure, and surface mount device (SMD) pads are disposed in a lowest level of the n levels of metal interconnect of the RDL structure;
forming a passivation layer covering the RDL structure;
subjecting the passivation layer to a lithographic process to form bump pad openings in the passivation layer and an SMD opening in the passivation layer and the dielectric layer, wherein the bump pads are exposed, respectively, through the bump pad openings, and the SMD pads are exposed through the SMD opening;
forming bumps on the bump pads through the bump pad openings, respectively; and
mounting a passive element on the SMD pads within the SMD opening.

17. The method for fabricating a microelectronic package according to claim 16, wherein the passivation layer comprises a polyimide layer.

18. The method for fabricating a microelectronic package according to claim 16, wherein the bumps comprises C4 bumps.

19. The method for fabricating a microelectronic package according to claim 16, wherein each of the bumps comprises a metal stud and a solder layer on the metal stud.

20. The method for fabricating a microelectronic package according to claim 16, wherein before mounting the passive element on the SMD pads, the method further comprises:
performing a pre-cleaning process to remove unwanted substance from an exposed top surfaces of the SMD pads.

21. The method for fabricating a microelectronic package according to claim 16, wherein the passive element comprises a decoupling capacitor, a resistor, an inductor, or an integrated passive device (IPD).
